(19) United States
(12) Patent Application Publication
(10) Pub. No.: US 2019/0088441 A1
(43) Pub. Date: Mar. 21, 2019

(54) ELECTRON EMISSION TUBE, ELECTRON IRRADIATION DEVICE, AND METHOD OF MANUFACTURING ELECTRON EMISSION TUBE

(71) Applicant: HAMAMATSU PHOTONICS K.K., Hamamatsu-shi (JP)

(72) Inventors: Motohiro SUYAMA, Hamamatsu-shi (JP); Takaaki NAGATA, Hamamatsu-shi (JP)

(73) Assignee: HAMAMATSU PHOTONICS K.K., Hamamatsu-shi (JP)

(21) Appl. No.: 16/131,413

(22) Filed: Sep. 14, 2018

(30) Foreign Application Priority Data
Sep. 20, 2017 (JP) 2017-180270

(51) Int. Cl. H01J 37/18; H01J 37/244; H01J 37/065; H01J 37/073

(52) U.S. Cl. CPC H01J 37/18; H01J 37/244; H01J 2237/04735; H01J 37/073; H01J 2237/2448; H01J 37/065

(57) ABSTRACT

An electron emission tube includes a housing in which an internal space is provided and which keeps the internal space in vacuum, an electron source that is arranged on a first end side in one direction of the housing and that generates an electron, a gate valve that is arranged on a second end side in the one direction of the housing and that can switch the second end side between an open state and a blocked state, and a partition part that is placed between the electron source and the gate valve and that divides the internal space into a first region including the electron source and a second region including the gate valve. The partition part includes an electron-permeable membrane that transmits an electron.

### TECHNICAL FIELD

The present disclosure relates to an electron emission tube, an electron irradiation device, and a method of manufacturing the electron emission tube.

### BACKGROUND

An electron emission tube that is used in a scanning electron microscope (SEM), a semiconductor exposure device, a semiconductor inspection device, and the like and that is to supply an electron is known. Japanese Unexamined Patent Publication. No. 2004-361096 describes that an electron beam emission tube (electron emission tube) including a gate valve that brings a body part into an airtight state by blocking a communication part, which communicates the body part and a head part, with an openable/closable gate plate. Japanese Unexamined Patent Publication No. 2001-84948 describes that a charged particle beam irradiation device in which a partition wall between a charged particle beam source (electron source) and a reactor where an irradiated object is arranged is movable and in which a gate valve is provided on a beam upstream side.

### SUMMARY

In order to keep an internal part of a housing to house an electron source, which generates an electron, in a high vacuum state, there is a case where an electron-permeable membrane is provided at a position where the electron generated in the electron source is emitted to the outside of the housing in an electron emission tube. While contributing to keeping the internal part of the housing in a high vacuum state, the electron-permeable membrane causes an energy loss when an electron passes through the electron-permeable membrane. In order to limit the energy loss of the electron, it is preferable to reduce a thickness of the electron-permeable membrane. However, when a thickness of the electron-permeable membrane is reduced, there is a possibility that the electron-permeable membrane is broken due to an atmospheric pressure difference between the internal part of the housing and an external part of the housing in manufacture, transportation, maintenance, and the like of the electron emission tube that houses the electron source.

In the present disclosure, an electron emission tube, an electron irradiation device, and a method of manufacturing the electron emission tube with which it is possible to reduce a thickness of an electron-permeable membrane are described.

An electron emission tube according to an aspect of the present disclosure includes a housing in which an internal space is provided and which keeps the internal space in vacuum, an electron source that is arranged on a first end side in one direction of the housing and that generates an electron, a gate valve that is arranged on a second end side in the one direction of the housing and that can switch the second end side between an open state and a blocked state, and a partition part that is placed between the electron source and the gate valve and that divides the internal space into a first region including the electron source and a second region including the gate valve. The partition part includes an electron-permeable membrane that transmits an electron.

In this electron emission tube, the electron source is arranged on the first end side in the one direction of the housing and the gate valve is arranged on the second end side in the one direction of the housing. The gate valve can switch the second end side of the housing between the open state and the blocked state. The internal space provided in the housing is divided into the first region including the electron source and the second region including the gate valve by the partition part including the electron-permeable membrane that transmits an electron. In manufacture or the like of the electron emission tube, it is possible to keep the first region and the second region in a vacuum state by blocking the second end side in the one direction of the housing with the gate valve. Thus, an atmospheric pressure difference between the first region and the second region becomes small, and force that is due to the atmospheric pressure difference and that is applied to the electron-permeable membrane arranged between the first region and the second region is reduced. As a result, it becomes possible to reduce a thickness of the electron-permeable membrane.

A potential of the electron-permeable membrane may be a ground potential. In this case, since voltage is not applied to the electron-permeable membrane, a physical deformation of the electron-permeable membrane due to voltage application is suppressed. As a result, it becomes possible to reduce an influence on an electron passing through the electron-permeable membrane.

The electron emission tube may further include an acceleration electrode which is arranged in the internal space and to which voltage with a potential higher than a potential of the electron source is applied. In this case, it becomes possible to accelerate an electron, which is generated in the electron source, by an electric field generated by the acceleration electrode a potential of which is higher than that of the electron source.

The electron-permeable membrane may be a membrane made of a single-layer substance. In this case, since a thickness of the single-layer substance is around that of one atom, it is possible to reduce the thickness of the electron-permeable membrane. As a result, it becomes possible to reduce an influence on an electron passing through the electron-permeable membrane.

The electron-permeable membrane may be a membrane made of single-layer or multi-layer graphene. In this case, since graphene has a thickness of one carbon atom, it is possible to reduce the thickness of the electron-permeable membrane. As a result, it becomes possible to reduce an influence on an electron passing through the electron-permeable membrane.

The electron-permeable membrane may be a silicon nitride membrane. In this case, since internal stress generated in manufacturing process is small in the silicon nitride membrane, it is possible to reduce a thickness of the electron-permeable membrane. As a result, it becomes possible to reduce an influence on an electron passing through the electron-permeable membrane.

The single-layer substance may be constituted by tungsten disulfide or molybdenum disulfide. In this case, since a thickness of the single-layer substance is around that of one atom included in tungsten disulfide or molybdenum disulfide, it is possible to reduce a thickness of the electron-permeable membrane. As a result, it becomes possible to reduce an influence on an electron passing through the electron-permeable membrane.

The partition part may include a substrate having a first surface that intersects with the one direction and a second surface that intersects with the one direction and that is provided on the opposite side of the first surface. A hole penetrating through the substrate in the one direction may be provided in the substrate. The electron-permeable membrane may be provided on the first surface and may cover the hole.

In this case, since the electron-permeable membrane is provided on the first surface of the substrate, it is possible to hold the electron-permeable membrane stably.

The partition part may include a holding member having an opening. The substrate may be fixed to the holding member by brazing or a metal seal. The opening and the hole may be arranged in such a manner as to overlap with each other. In this case, it is possible to keep a vacuum state of the first region by fixing the substrate, in which the electron-permeable membrane is provided, to the holding member by brazing or a metal seal. Thus, since it is possible to attach the substrate to the holding member after manufacture of the substrate in which the electron-permeable membrane is provided, manufacture of the electron-permeable membrane becomes easy.

The electron source may include a photoelectric surface that generates an electron when being irradiated with light. In this case, by the photoelectric surface being irradiated with light, an electron is generated in the housing and it becomes possible to emit the electron from the electron emission tube.

The photoelectric surface may be an alkali photoelectric surface. In this case, by the alkali photoelectric surface being irradiated with light in a visible-light region, an electron is generated in the housing and it becomes possible to emit the electron from the electron emission tube.

The electron source may be a thermionic source or a field emission electron source. In this case, by applying heat or an electric field to the electron source, an electron is generated in the housing and it becomes possible to emit the electron from the electron emission tube.

An electron irradiation device according to another aspect of the present disclosure is a device that irradiates an irradiated body with an electron. The electron irradiation device includes the above-described electron emission tube, and a housing chamber to which the electron emission tube is attached and which houses the irradiated body. Since this electron irradiation device includes the above-described electron emission tube, it becomes possible to reduce a thickness of an electron-permeable membrane.

The electron irradiation device may further include a detector that is arranged in the housing chamber and that detects a response signal generated by irradiating the irradiated body with an electron. In this case, it becomes possible to perform observation or inspection of the irradiated body.

A method of manufacturing the electron emission tube which method is according to another aspect of the present disclosure includes evacuating the first region and the second region by an exhaust device. The exhaust device includes a vacuum pump, a common tube extending from the vacuum pump, a first branch tube extending from the common tube and connected to the first region, and a second branch tube extending from the common tube and connected to the second region.

In this method of manufacturing the electron emission tube, since the first branch tube connected to the first region and the second branch tube connected to the second region are connected to the vacuum pump through the common tube, the first region and the second region are evacuated simultaneously by the exhaust device. Thus, since an atmospheric pressure difference between the first region and the second region becomes small, force that is due to the atmospheric pressure difference and that is applied to an electron-permeable membrane arranged between the first region and the second region is reduced in a manufacturing stage of the electron emission tube. As a result, it becomes possible to reduce a thickness of the electron-permeable membrane.

According to the present disclosure, it becomes possible to reduce a thickness of an electron-permeable membrane.

### BRIEF DESCRIPTION OF THE DRAWINGS

FIG. 1 is a cross-sectional view illustrating an internal part of an electron emission tube according to an embodiment;

FIG. 2A to FIG. 2F are views illustrating an example of a preparation step;

FIG. 3 is a view for describing an example of an air exhausting step and a sealing step;

FIG. 4 is a view for describing another example of an air exhausting step and a sealing step;

FIG. 5 is a view illustrating an application example of the electron emission tube in FIG. 1;

FIG. 6 is a view illustrating another example of an electron source; and

FIG. 7 is a cross-sectional view illustrating an inside of an electron emission tube according to a modification example.

### DETAILED DESCRIPTION

Hereinafter, an electron emission tube, an electron irradiation device, and a method of manufacturing an electron emission tube according to an embodiment will be described with reference to the drawings. The same sign is assigned to the same or equivalent parts in the drawings and an overlapped description is omitted.

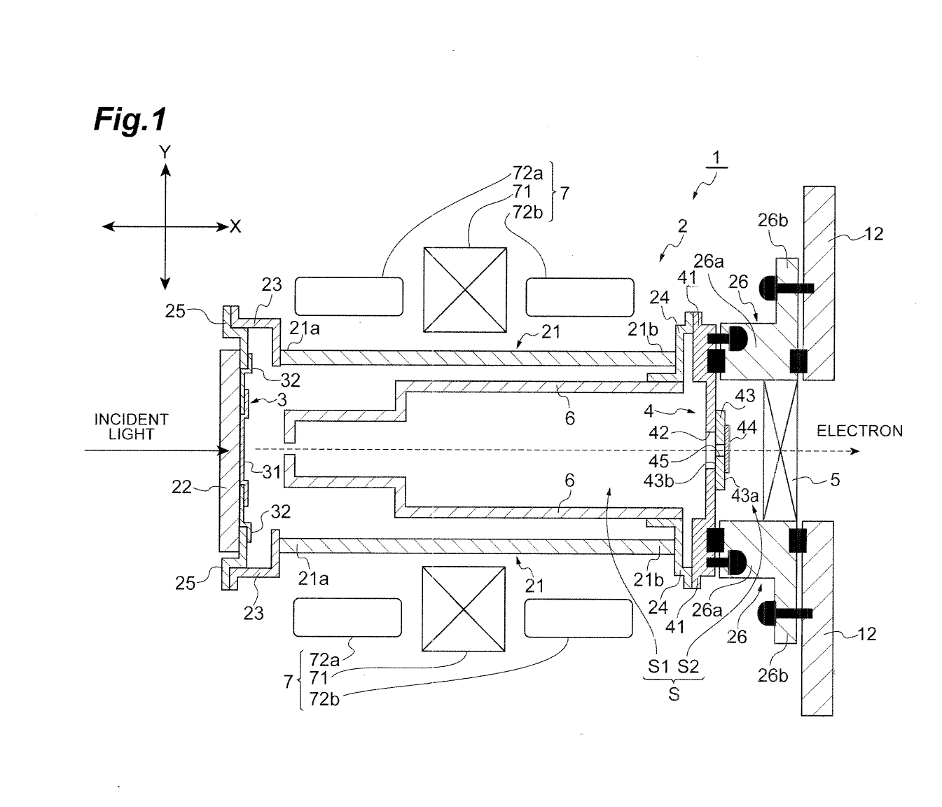

FIG. 1 is a cross-sectional view illustrating an internal part of an electron emission tube according to an embodiment. In FIG. 1, an electron emission tube 1 in a state of being attached to an attachment part 12 (described later) is illustrated. The electron emission tube 1 is a vacuum tube to supply an electron. The electron emission tube 1 includes a housing 2, an electron source 3, a partition part 4, a gate valve 5, an acceleration electrode 6, and an adjustment member 7.

The housing 2 is a container that extends in one direction (X-axis direction) and defines an internal space S. The housing 2 has a substantially cylindrical shape, for example. The housing 2 keeps the internal space S in vacuum. For example, the housing 2 keeps the internal space S in an ultrahigh vacuum state. The housing 2 includes a side wall part 21, an input surface plate 22, a flange 23, a flange 24, a flange 25, and a flange 26.

The side wall part 21 has a hollow cylindrical shape extending in the X-axis direction and has openings at both ends (end parts 21a and 21b) in the X-axis direction. A material of the side wall part 21 is, for example, borosilicate glass. The input surface plate 22 is a light transmissive glass substrate. The input surface plate 22 is provided at the end part 21a of the side wall part 21 in such a manner as to occlude the opening of the end part 21a.

The flange 23 is, for example, a metal annular member. The flange 23 is protruded to an outer side from the end part 21a of the side wall part 21. The flange 23 is provided along the end part 21a. The flange 23 is fixed to the end part 21a by fusion or the like. The flange 24 is, for example, a metal annular member. The flange 24 is protruded to the outer side from the end part 21b of the side wall part 21. The flange 24 is provided along the end part 21b. The flange 24 is fixed to the end part 21b by fusion or the like.

The flange 25 is, for example, a metal annular member. The flange 25 is protruded to the outer side from a circumference of the input surface plate 22. The flange 25 is provided annularly along the circumference of the input surface plate 22. The flange 23 and the flange 25 are combined to each other by welding or the like, whereby the input surface plate 22 is fixed to the end part 21a in such a manner as to keep airtightness of the internal space S.

The flange 26 includes a body part 26a and an attaching part 26b. The body part 26a is a hollow cylindrical-shaped part which extends in the X-axis direction and both ends of which are opened. The attaching part 26b is a part to attach the electron emission tube 1 to the attachment part 12. The body part 26a and the partition part 4 are fixed to each other, for example, by a copper gasket and bolt. The attaching part 26b is protruded to the outer side from an end part on the opposite side of the partition part 4 in the X-axis direction of the body part 26a. The attaching part 26b is provided along the end part. The attaching part 26b and the attachment part 12 are fixed to each other, for example, by a copper gasket and bolt.

The electron source 3 generates an electron and emits the generated electron to the internal space S. The electron source 3 is arranged on one end (first end) side in the X-axis direction of the housing 2. More specifically, the electron source 3 is provided on a surface of the input surface plate 22, the surface facing the internal space S. The electron source 3 includes a photoelectric surface (photocathode) 31 and an electrode 32.

The photoelectric surface 31 generates an electron from light entering from an external part of the electron emission tube 1 through the input surface plate 22 and emits the electron to the internal space S. The photoelectric surface 31 is provided along the surface of the input surface plate 22, the surface facing the internal space S. The electrode 32 is connected to an outer circumference of the photoelectric surface 31. A material of the electrode 32 is, for example, chromium (Cr). For example, voltage of −10 kV is applied to the photoelectric surface 31 by the electrode 32. The photoelectric surface 31 is, for example, an alkali photoelectric surface having high sensitivity in a visible-light region. A bialkali photoelectric surface having high sensitivity in a blue region in visible light or a multialkali photoelectric surface having high sensitivity in a red region may be used as the alkali photoelectric surface. Since the bialkali photoelectric surface has high resistance and has a tendency that a response to strong light is saturated, a light transmissive base of a conducting layer may be provided in a case where the bialkali photoelectric surface is used.

The gate valve 5 is provided on the other end (second end) side in the X-axis direction of the housing 2. The gate valve 5 switches the other end side in the X-axis direction of the housing 2 between an open state and a blocked state. The gate valve 5 includes a gate plate (not illustrated) that can open/close the other end side in the X-axis direction of the housing 2. The other end side in the X-axis direction of the housing 2 is switched to the open state or the blocked state by a change in a position of the gate plate.

The partition part 4 divides the internal space S into a first region S1 including the electron source 3 and a second region S2 including the gate valve 5. The first region S1 is a space defined by the side wall part 21, the input surface plate 22, the flange 23, the flange 24, the flange 25, and the partition part 4. Since the members that define the first region S1 are fixed to each other by fusion, welding, and the like, a degree of vacuum of the first region S1 after the first region S1 is brought into a vacuum state is kept. Note that a method of bringing the first region S1 into the vacuum state will be described later.

The second region S2 is a space defined by the flange 26, the partition part 4, and the gate valve 5. The other end side in the X-axis direction of the housing 2 is switched to the blocked state by the gate valve 5 and the blocked state is maintained, whereby a degree of vacuum of the second region S2 after the second region S2 is brought into the vacuum state is kept. When the other end side in the X-axis direction of the housing 2 is switched to the open state by the gate valve 5 after the electron emission tube 1 is attached to the attachment part 12, the second region S2 is connected to an internal space of a housing chamber 11 (described later). Note that a method of bringing the second region S2 into the vacuum state will be described later.

The partition part 4 includes a holding member 41 having an opening 42, a substrate 43, and an electron-permeable membrane 44. The holding member 41 is a plate-like member extending in a direction vertical to the X-axis direction. An outer circumference part of the holding member 41 is held between the flange 24 and the flange 26. The outer circumference part of the holding member 41 is fixed to an outer circumference part of the flange 24 by welding or the like and is fixed to the body part 26a by a copper gasket, bolt, and the like. In the holding member 41, the opening 42 penetrating through the holding member 41 in the X-axis direction is provided at a substantially center position of the holding member 41 when viewed from the X-axis direction.

The substrate 43 includes a first surface 43a and a second surface 43b that intersect with the X-axis direction. A hole 45 penetrating through the substrate 43 in the X-axis direction is provided in the substrate 43. A material of the substrate 43 is, for example, silicon or glass. The electron-permeable membrane 44 is provided on the first surface 43a in such a manner as to cover the hole 45. The electron-permeable membrane 44 is, for example, a membrane made of single-layer graphene. Note that graphene is constituted by a single carbon atom layer. Graphene is a sheet-shaped substance having a thickness of one carbon atom. The second surface 43b is fixed to the holding member 41 by a metal seal in such a manner that the hole 45 and the opening 42 overlap with each other. Note that the substrate 43 may be fixed to the holding member 41 by brazing. For example, voltage of 0 V (ground potential) is applied to the electron-permeable membrane 44.

The acceleration electrode 6 is an electrode to accelerate an electron emitted from the electron source 3. The acceleration electrode 6 is arranged in the internal space S. More specifically, the acceleration electrode 6 is provided in such a manner as to extend in the X-axis direction in the first region S1. A radius of the acceleration electrode 6 is gradually increased from one end in the X-axis direction that is close to the electron source 3 to the other end in the X-axis direction. The other end in the X-axis direction of the acceleration electrode 6 is fixed to an inner circumference part of the flange 24 by resistance welding or the like. Voltage a potential of which is higher than that of the photoelectric surface 31 is applied to the acceleration electrode 6. For example, voltage of 0 V (ground potential) is applied to the acceleration electrode 6. An electron emitted from the photoelectric surface 31 is accelerated by an electric field generated by the photoelectric surface 31 and the acceleration electrode 6.

The adjustment member 7 is a coil to adjust a convergence region of an electron and a moving direction of the electron. The adjustment member 7 includes a convergence coil 71 and deflection coils 72a and 72b that are arranged in such a manner as to surround an outer circumference of the side wall part 21. When current flows in the convergence coil 71 and the deflection coils 72a and 72b, a magnetic field is generated in the first region S1. On the basis of the magnetic field generated by the convergence coil 71 and the deflection coils 72a and 72b, a convergence region of an electron and a moving direction of the electron are adjusted.

More specifically, the convergence coil 71 adjusts a convergence region of an electron group including a plurality of electrons emitted from the photoelectric surface 31. Here, the convergence region is a region, through which the electron group passes, in a surface vertical to the X-axis direction. The convergence coil 71 adjusts the convergence region of the electron group in such a manner that the convergence region of the electron group in the electron-permeable membrane 44 becomes the smallest. By the adjustment in such a manner that the convergence region of the electron group becomes the smallest in the electron-permeable membrane 44, a diameter of a minimum effective area of the electron-permeable membrane 44 becomes around 0.1 mm to 0.5 mm, for example. On the other hand, the deflection coil 72a and the deflection coil 72b are provided in such a manner as to sandwich the convergence coil 71 in the X-axis direction. The deflection coils 72a and 72b generate a magnetic field to change a direction in which the electron group moves (moving direction). Note that the adjustment member 7 may adjust a convergence region of an electron group and a moving direction of an electron by generating an electric field in the first region S1.

In the electron emission tube 1 configured in the above manner, the photoelectric surface 31 generates an electron and emits the electron to the first region S1 when incident light enters the photoelectric surface 31 through the input surface plate 22. The electron emitted from the photoelectric surface 31 to the first region S1 is accelerated in the X-axis direction by the acceleration electrode 6. Here, a convergence region and a moving direction of the electron are adjusted by the adjustment member 7 and the electron passes through the electron-permeable membrane 44. The electron passing through the electron-permeable membrane 44 passes through the second region S2 and is emitted from the electron emission tube 1 through the gate valve 5.

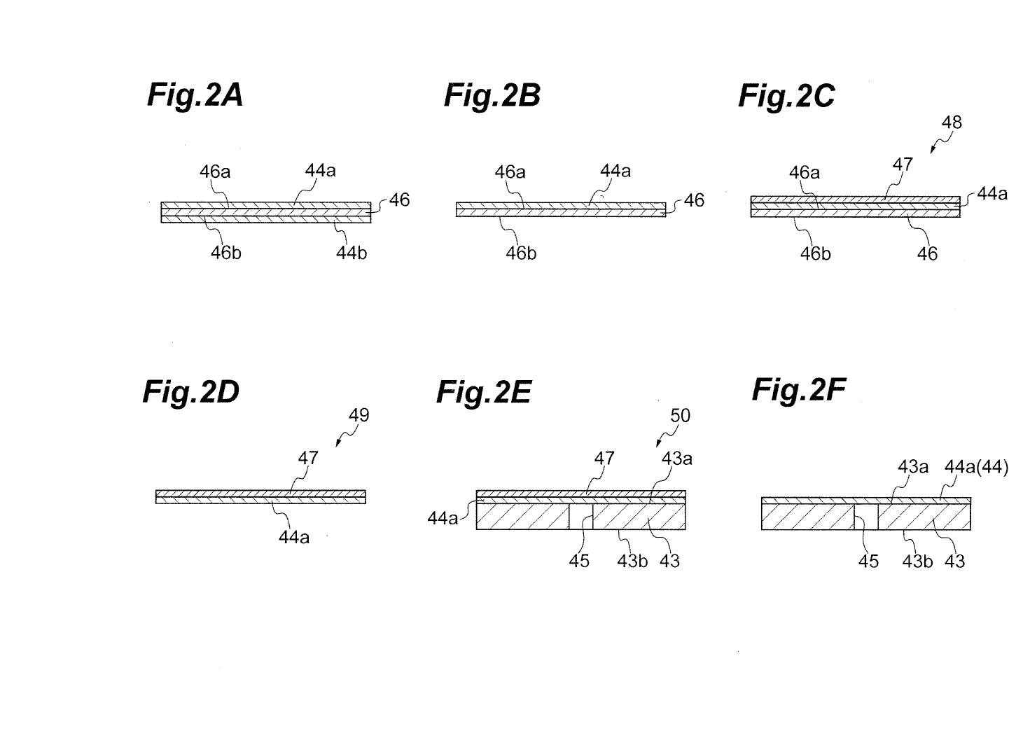

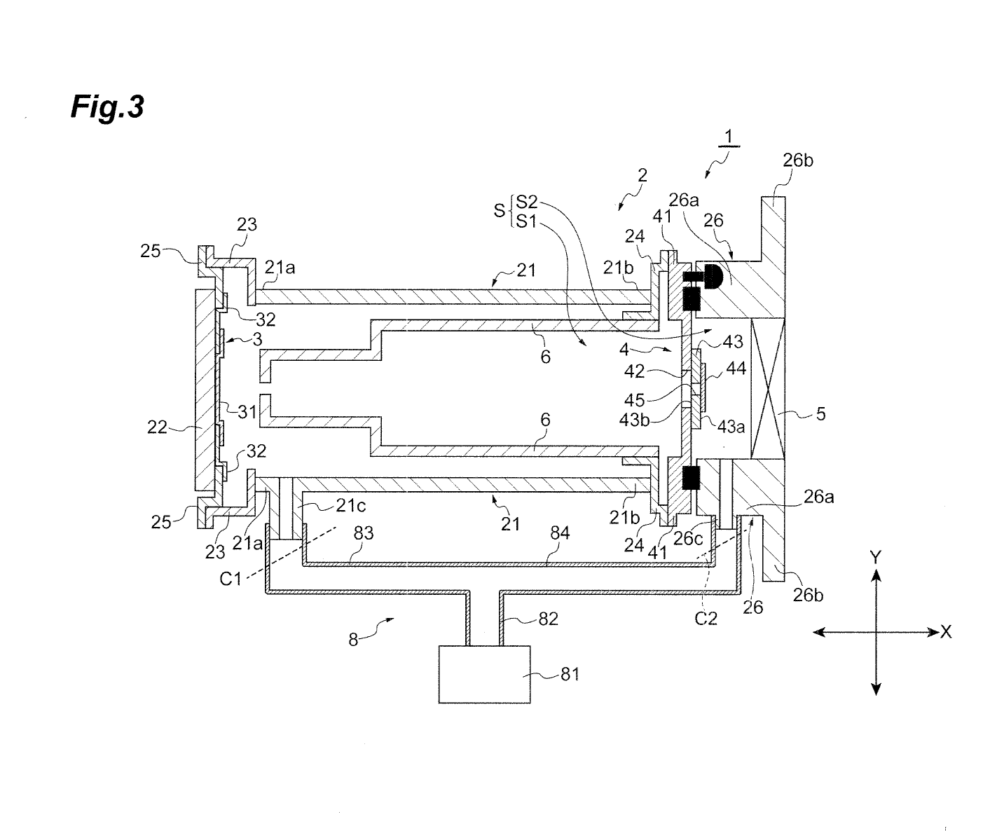

Next, a method of manufacturing the electron emission tube 1 will be described with reference to FIG. 2A to FIG. 2F, and FIG. 3. FIG. 2A to FIG. 2F are views illustrating an example of a preparation step. FIG. 3 is a view for describing an example of an air exhausting step and a sealing step. The method of manufacturing the electron emission tube 1 includes a preparation step, an air exhausting step, a photoelectric surface manufacturing step, and a sealing step.

In the preparation step, a membrane made of single-layer graphene (electron-permeable membrane 44) is formed on a substrate 43. More specifically, first, membranes of the single-layer graphene 44a and 44b are respectively formed on both surfaces (surfaces 46a and 46b) of copper foil 46 by thermal chemical vapor deposition (CVD) as illustrated in FIG. 2A. For example, when methane (CH₄) is used as a carbon source, time of supplying CH₄ is set to 450 seconds, and a membrane forming temperature is set to 1020° C., membranes of the single-layer graphene 44a and 44b are formed on the copper foil 46. The membrane of the single-layer graphene 44a is formed on the surface 46a and the membrane of the single-layer graphene 44b is formed on the surface 46b. For example, copper foil a degree of purity or which is around 99.9% and a thickness of which is around 30 μm is used as the copper foil 46.

Subsequently, as illustrated in FIG. 2B, the single-layer graphene 44b formed on the surface 46b of the copper foil is removed by reactive ion etching (RIE). Subsequently, as illustrated in FIG. 2C, polymethyl methacrylate (PMMA) 47 is applied to the single-layer graphene 44a by a spin coater or the like, whereby a first intermediate 48 is formed. For example, the PMMA 47 of around 4 weight percent (wt %) is applied to the single-layer graphene 44a with a rotational speed of the spin coater being 3000 rotations per minute (rpm).

Subsequently, the first intermediate 48 is floated on ammonium persulfate of around 1 wt %, whereby the copper foil 46 is removed and a second intermediate 49 is manufactured as illustrated in FIG. 2D. Subsequently, after the second intermediate 49 is floated on pure water, the second intermediate 49 is skimmed with the substrate 43 in which a hole 45 having an intended size is provided. Then, the substrate 43 and the single-layer graphene 44a are dried, whereby the single-layer graphene 44a is transferred to the first surface 43a of the substrate 43, whereby a third intermediate 50 is manufactured as illustrated in FIG. 2E. Finally, the third intermediate 50 is heated at around 450° C. in a hydrogen atmosphere and in a vacuum state (vacuum-baked in hydrogen atmosphere), whereby the PMMA 47 is removed as illustrated in FIG. 2F. Accordingly, the substrate 43 in which a membrane made of the single-layer graphene 44a (electron-permeable membrane 44) is provided is manufactured.

Next, in the preparation step, the substrate 43 in which the membrane made of the single-layer graphene 44a (electron-permeable membrane 44) is provided is fixed to the holding member 41 illustrated in FIG. 1 by aluminum joining (metal seal). More specifically, an aluminum ring is arranged between the second surface 43b of the substrate 43, and one surface of the holding member 41 that faces a gate valve 5, and the arranged aluminum ring is heated and pressed. Thus, the substrate 43 and the holding member 41 are fixed in such a manner as to keep airtightness of a first region S1.

In the air exhausting step, a first region S1 and a second region S2 are evacuated by an exhaust device 8 illustrated in FIG. 3. More specifically, the exhaust device 8 exhausts the air in the first region S1 and the second region S2, whereby the first region S1 and the second region become a vacuum state.

The exhaust device 8 includes a vacuum pump 81, a common tube 82, a branch tube (first branch tube) 83, and a branch tube (second branch tube) 84. The vacuum pump 81 only needs to be a pump that can evacuate the first region S1 and the second region S2 into an intended degree of vacuum. For example, each of the common tube 82, the branch tube 83, and the branch tube 84 is made of copper and is a hollow cylindrical pipe. One end of the common tube 82 is connected to the vacuum pump 81. The other end of the common tube 82 is connected to one end of the branch tube 83 and one end of the branch tube 84. The other end of the branch tube 83 is connected to the first region S1 by being fixed, by brazing or the like, to a narrow tube 21c provided in a side wall part 21. The other end of the branch tube 84 is connected to the second region S2 by being fixed, by brazing or the like, to a narrow tube 26c provided in a flange 26. In such a manner, both of the first region S1 and the second region S2 are connected to the vacuum pump 81 by the common tube 82 extending from the vacuum pump 81, and the branch tube 83 and branch tube 84 extending from the common tube 82. By activation of the vacuum pump 81 in this state, the first region S1 and the second region S2 are simultaneously evacuated.

In the photoelectric surface manufacturing step, an alkali photoelectric surface (photoelectric surface 31) is produced by reaction of alkali metal with an antimony base in a vacuum state. More specifically, for example, degassing (removal of impurity) of the first region S1 is performed by performance of baking, in which the electron emission tube 1 is heated, at 300° C. for a several hours after the first region S1 is evacuated. Subsequently, alkali metal such as potassium, sodium, and cesium is introduced from a narrow tube (not illustrated) into the first region S1 and the alkali metal is made to react with an antimony base previously provided in the first region S1, whereby an alkali photoelectric surface is manufactured.

In the sealing step, each of the evacuated first region S1 and second region S2 is sealed to be maintained in the vacuum state. Specifically, each of the other end side of the branch tube 83 and the other end side of the branch tube 84 is sealed. More specifically, the other end side of the branch tube 83 is sealed at a position of a broken line C1 illustrated in FIG. 3 by a pinch sealing method, whereby the first region S1 is sealed in such a manner that the vacuum state is maintained. In the pinch sealing method, for example, the branch tube 83 is pressed and crushed from the outside of the branch tube 83 at the position of the broken line C1 illustrated in FIG. 3 of the branch tube 83, whereby the branch tube 83 is occluded. Similarly, the other end side of the branch tube 84 is sealed at a position of a broken line C2 illustrated in FIG. 3 by the pinch sealing method, whereby the second region S2 is sealed in such a manner that the vacuum state is maintained. Note that in the air exhausting step, the photoelectric surface manufacturing step, and the sealing step, the other end side in an X-axis direction of a housing 2 is maintained in a blocked state by the gate valve 5. After the first region S1 and the second region S2 are sealed, the first region S1 and the second region S2 are kept in the vacuum state by the housing 2 or the like. The electron emission tube 1 is manufactured in the above manner. Note that although the electron emission tube 1 includes the narrow tube 21c, the narrow tube 26c, a part of the branch tube 83, and a part of the branch tube 84 after manufacture of the electron emission tube 1, these are not illustrated in FIG. 1.

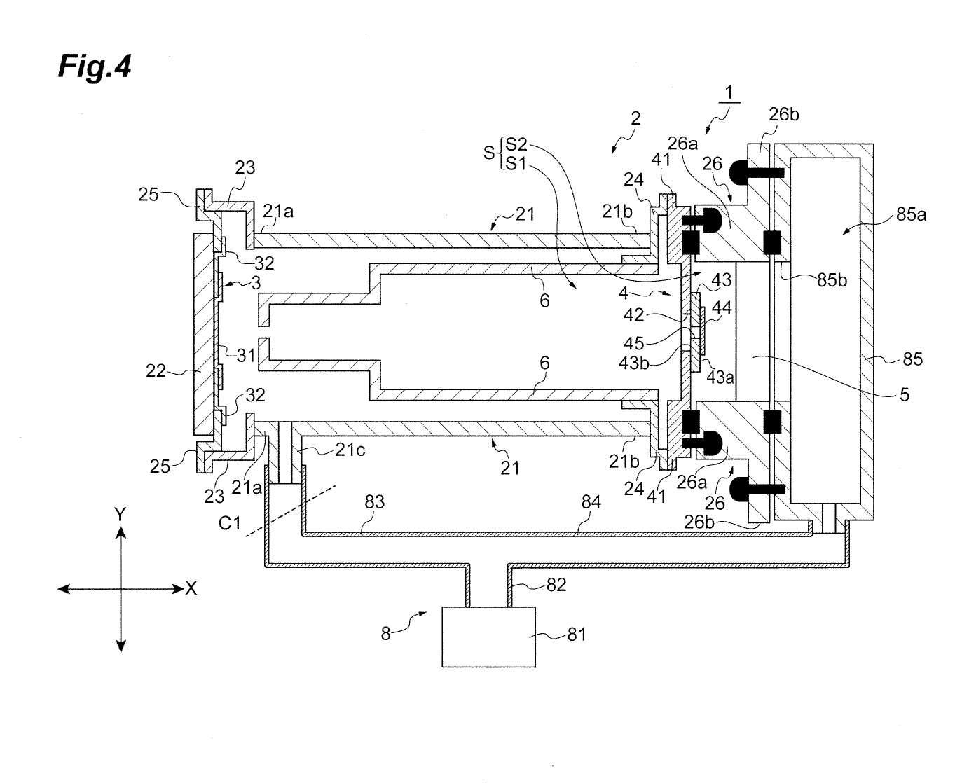

Next, another example of an air exhausting step and a sealing step will be described. FIG. 4 is a view for describing another example of an air exhausting step and a sealing step. The example illustrated FIG. 4 is different from the example illustrated in FIG. 3 in a connection form between a branch tube 84 and a second region S2. More specifically, an exhaust device 8 further includes an exhaust chamber 85. The exhaust chamber 85 is a substantially rectangular parallelepiped box body having a space 85a provided inside of the exhaust chamber 85, and a branch tube 84 is connected to the exhaust chamber 85. At one end in an X-axis direction of the exhaust chamber 85, for example, an opening 85b is provided. The opening 85b has substantially the same area with a surface vertical to the X-axis direction of a gate valve 5. The one end in the X-axis direction of the exhaust chamber 85 is fixed to an attaching part 26b of a flange 26, for example, by a copper gasket and bolt.

In the air exhausting step, first, the other end side in the X-axis direction of a housing 2 is brought into an open state by the gate valve 5. When the other end side of the housing 2 becomes the open state, the second region S2 and the space 85a become a continuous space region and the branch tube 84 is connected to the second region S2 through the exhaust chamber 85. By activation of a vacuum pump 81 in this state, a first region S1 and the second region S2 are simultaneously evacuated. In the sealing step, the exhaust chamber 85 is detached from the attaching part 26b of the flange 26 after the other end side in the X-axis direction of the housing 2 is brought into a blocked state by the gate valve 5, whereby the second region S2 is sealed in such a manner as to be maintained in a vacuum state. In this example, the second region S2 is evacuated through the exhaust chamber 85 and the second region S2 is sealed by the gate valve 5. Thus, it is possible to omit a step of sealing the branch tube 84 by a pinch sealing method.

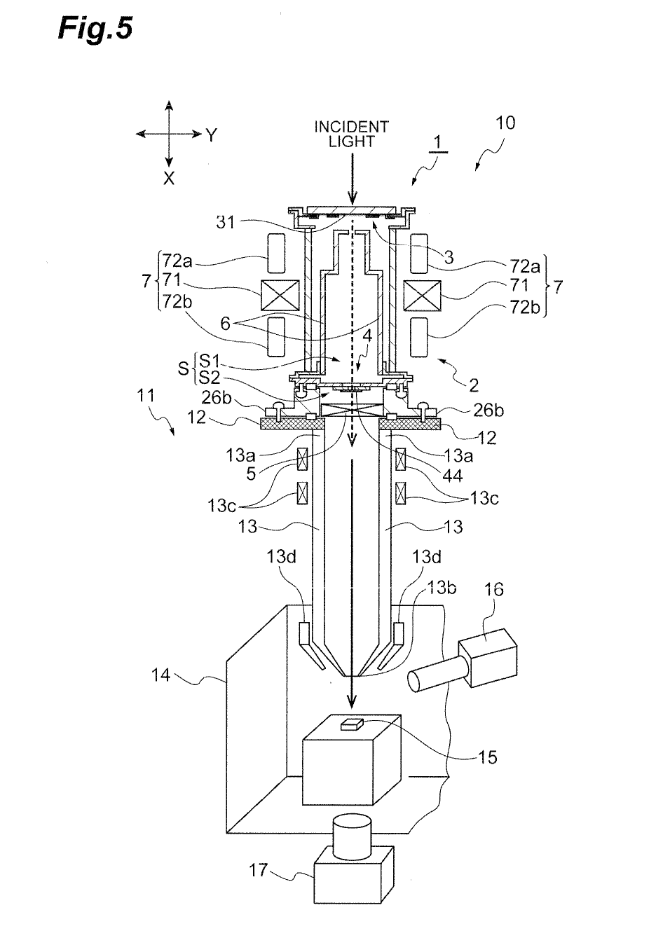

Next, an application example of an electron emission tube according to the present embodiment will be described with reference to FIG. 5. FIG. 5 is a view illustrating an application example of the electron emission tube 1 in FIG. 1. In FIG. 5, an electron irradiation device 10 including the electron emission tube 1 is illustrated as an application example. The electron irradiation device 10 is a device that irradiates an irradiated body 15 with an electron. The electron irradiation device 10 includes the electron emission tube 1 and a housing chamber 11. The housing chamber 11 is a box body to house the irradiated body 15 and irradiate the irradiated body 15 with an electron. The housing chamber 11 is also called a vacuum chamber. The housing chamber 11 includes a mirror body 13 and a sample chamber 14. The electron emission tube 1 is attached to an end part in an X-axis direction of the housing chamber 11. More specifically, the attaching part 26b of the electron emission tube 1 is fixed to an attachment part 12 provided in one end part 13a of the mirror body 13 by a copper gasket and bolt. Note that the attachment part 12 is a plate-like member extending in a direction vertical to the X-axis direction.

The mirror body 13 has a hollow cylindrical shape extending in the X-axis direction. The mirror body 13 has openings at both ends (end parts 13a and 13b) in the X-axis direction. The attachment part 12 is provided in the end part 13a. The end part 13b is close to the irradiated body 15 in the X-axis direction. A magnetic field convergence lens 13c and a magnetic field objective lens 13d are arranged on an outer side of the mirror body 13. In an end part 13b of the mirror body 13, a radius of the mirror body 13 is gradually decreased as getting closer to the irradiated body 15. An opening area of the end part 13b is smaller than an opening area of the end part 13a. An electron supplied by the electron emission tube 1 is emitted from the end part 13b of the mirror body 13 with a convergence region thereof being narrowed down by a magnetic field generated by the magnetic field convergence lens 13c and the magnetic field objective lens 13d.

The sample chamber 14 houses the irradiated body 15. The irradiated body 15 is irradiated with an electron emitted from the mirror body 13. A detector 16 is arranged in the housing chamber 11. More specifically, the detector 16 is provided in the sample chamber 14 and detects, as a response signal, a secondary electron generated from the irradiated body 15 irradiated with an electron. A vacuum pump 17 can be connected to the sample chamber 14. When the irradiated body 15 is irradiated with an electron, an internal space of the mirror body 13 and the sample chamber 14 is evacuated by the vacuum pump 17. After the internal space of the mirror body 13 and the sample chamber 14 is evacuated, the other end side in the X-axis direction of the electron emission tube 1 is brought into an open state by the gate valve 5.

In the electron irradiation device 10, for example, a photoelectric surface 31 is irradiated with a laser beam (incident light) converged into 1 μm or smaller. An electron emitted from the photoelectric surface 31 which is irradiated with the laser beam is accelerated by an acceleration electrode 6 and passes through an electron-permeable membrane 44 with a convergence region of the electron being reduced to around 1/10 by a magnetic field generated by the convergence coil 71. The electron passing through the electron-permeable membrane 44 is emitted from the electron emission tube 1 and supplied to the housing chamber 11. A convergence region of the electron supplied to the housing chamber 11 is further reduced to around 1/100 by a magnetic field generated by the magnetic field convergence lens 13c and the magnetic field objective lens 13d arranged on the outer side of the mirror body 13. Then, the irradiated body 15 is irradiated with the electron. For example, it is possible to acquire a microscopic image with a spatial resolution being 1 nm by measuring, with the detector 16, an amount of change of the secondary electron emitted from the irradiated body 15 irradiated with an electron.

The electron emission tube 1 is manufactured separately from the housing chamber 11 and is attached to the housing chamber 11 after manufacture of the electron emission tube 1. Also, in a case where the electron emission tube 1 is replaced or maintained, the electron emission tube 1 is detached from the housing chamber 11, and a new electron emission tube 1 or a maintained electron emission tube 1 is attached to the housing chamber 11. In a state in which the electron emission tube 1 is not attached to the housing chamber 11, the other end, side in the X-axis direction of a housing 2 of the electron emission tube 1 is maintained in a blocked state by the gate valve 5. After the electron emission tube 1 is attached to the housing chamber 11, the other end side in the X-axis direction of the housing 2 of the electron emission tube 1 is opened by the gate valve 5 when an electron is supplied.

Examples of the electron irradiation device 10 include a scanning electron microscope, a semiconductor exposure device, and a semiconductor inspection device. Also, as the electron irradiation device 10, there is a microfocus x-ray tube (x-ray non-destructive testing device) that requires an x-ray emitted from a very small point. Moreover, as the electron irradiation device 10, there is an electronic beam exposure device that requires a multiple electron beam generated by irradiating a photoelectric surface 31 with a lot of laser beams or a pattern electron beam formed by irradiating a photoelectric surface 31 with, pattern light.

In the above-described electron emission tube 1, the electron source 3 is arranged on one end side in one direction (X-axis direction) of the housing 2 and the gate valve 5 that can switch the other end side of the housing 2 between the open state and the blocked state is arranged on the other end side in the one direction (X-axis direction) of the housing 2. The internal space S provided in the housing 2 is divided into the first region S1 including the electron source 3 and the second region S2 including the gate valve 5 by the partition part 4 including the electron-permeable membrane 44 configured to transmit an electron. In manufacture, transport, maintenance, and the like of the electron emission tube 1, the electron emission tube 1 is detached from the attachment part 12. In this case, it is possible to keep the first region S1 and the second region S2 in a vacuum state by blocking the other end side in the one direction of the housing 2 by the gate valve 5. Thus, an atmospheric pressure difference between the first region S1 and the second region S2 becomes small, and force that is due to the atmospheric pressure difference and that is applied to the electron-permeable membrane 44 arranged between the first region S1 and the second region S2 is reduced. As a result, it becomes possible to reduce a thickness of the electron-permeable membrane 44.

A potential of the electron-permeable membrane 44 is a ground potential. Since voltage is not applied to the electron-permeable membrane 44, it is possible to suppress a physical deformation of the electron-permeable membrane 44 due to voltage application. As a result, it becomes possible to reduce an influence on an electron passing through the electron-permeable membrane 44.

The electron emission tube 1 includes the acceleration electrode 6 arranged in the internal space S. Voltage a potential of which is higher than a potential of the electron source 3 is applied to the acceleration electrode 6. It becomes possible to accelerate an electron generated in the electron source 3 by an electric field generated by the acceleration electrode 6a potential of which is higher than that of the electron source 3.

The electron-permeable membrane 44 is a membrane made of single-layer graphene 44a. Since the membrane made of the single-layer graphene 44a can stand by itself, a thickness of the electron-permeable membrane 44 can be reduced. Since a thickness of the membrane made of the single-layer graphene 44a is that of one carbon atom, it becomes possible to reduce an influence on an electron passing through the electron-permeable membrane 44. Since the thickness of the membrane made of the single-layer graphene 44a is around 0.35 nm, it is possible to maintain a vacuum state of the first region S1 and to limit an energy loss of when an electron passes through the electron-permeable membrane 44. Since graphene is constituted by a carbon atom of a small atomic number, a probability that an electron interacts with the electron-permeable membrane 44 becomes low and it becomes possible to reduce heat generation by the electron-permeable membrane 44 even when an amount of electrons emitted from the electron emission tube 1 is increased. Also, since the membrane made of the single-layer graphene 44a is thin in thickness, it becomes possible to limit a loss of an energy distribution and an angular distribution of an electron that are originally held by the photoelectric surface 31. Thus, it becomes possible to suppress a decrease in electrons that can be effectively used in the housing chamber 11.

The partition part 4 includes the substrate 43 including the first surface 43a that intersects with one direction (X-axis direction) and the second surface 43b that intersects with the one direction (X-axis direction) and that is provided on the opposite side of the first surface 43a. The hole 45 penetrating through the substrate 43 in the one direction (X-axis direction) is provided in the substrate 43. The electron-permeable membrane 44 is provided on the first surface 43a and covers the hole 45. Since the electron-permeable membrane 44 is provided on the first surface 43a of the substrate 43, it becomes possible for the substrate 43 to hold the electron-permeable membrane 44. Also, it becomes possible to define a region, through which an electron passes, in the electron-permeable membrane 44 by a size of the hole 45 provided in the substrate 43.

The partition part 4 includes the holding member 41 having the opening 42. The substrate 43 is fixed to the holding member 41 by brazing or a metal seal. The opening 42 and the hole 45 are arranged in such a manner as to overlap with each other. It is possible to keep a vacuum state of the first region S1 by fixation of the substrate 43 on which the electron-permeable membrane 44 is provided to the holding member 41 by brazing or a metal seal. Thus, since it is possible to attach the substrate 43 to the holding member 41 after manufacture of the substrate 43 on which the electron-permeable membrane 44 is provided, manufacture of the electron-permeable membrane 44 becomes easy.

The electron source 3 includes the photoelectric surface 31 that generates an electron when being irradiated with light (incident light). When the photoelectric surface 31 is irradiated with light, an electron is generated in the first region S1 in the housing 2, whereby it becomes possible to emit the electron from the electron emission tube 1. When the photoelectric surface 31 is irradiated with light patterned on a two-dimensional plane, an electron having a two-dimensional distribution corresponding to the patterned light is emitted from the photoelectric surface 31. Thus, since it is only necessary to pattern light with which the photoelectric surface 31 is irradiated in such a manner that an electron having an intended two-dimensional distribution is emitted, it becomes easy to emit the electron having the intended two-dimensional distribution from the electron emission tube 1. Accordingly, it becomes easy to irradiate the irradiated body 15 of the electron irradiation device 10 with the electron having the intended two-dimensional distribution. Also, it is possible to control timing of emission of an electron emitted from the electron emission tube 1 by controlling timing at which the photoelectric surface 31 generates an electron using incident light with which the photoelectric surface 31 is irradiated as a pulsed wave. Thus, it becomes easy to control timing at which the electron irradiation device 10 irradiates the irradiated body 15 with an electron. For example, it becomes possible to inspect an operation of the irradiated body 15 by irradiating the irradiated body 15 with an electron in synchronization with the operation of the irradiated body 15 provided in the housing chamber 11.

In a case where the photoelectric surface 31 is an alkali photoelectric surface, it is possible to generate an electron in the housing 2 by irradiating the alkali photoelectric surface with light in a visible-light region. For example, the alkali photoelectric surface has high sensitivity n a visible-light region in which a wavelength of light is around 400 run. It is easier to pattern a laser beam on a two-dimensional plane in the visible-light region than in a different wavelength region of light. Thus, it becomes easier to emit an electron having an intended two-dimensional distribution from the electron emission tube 1.

In a case where incident light having energy slightly larger than a work function of the photoelectric surface 31 enters the photoelectric surface 31, an electron emitted from the photoelectric surface 31 has a relatively low energy distribution. For example, in a case where the photoelectric surface 31 is a bialkali photoelectric surface, when the bialkali photoelectric surface is irradiated with incident light having a wavelength of 532 nm, an electron emitted from the bialkali photoelectric surface has an energy distribution of around 0.1 eV that is around 1/10 of that of a tungsten electron gun. Thus, it becomes easy to converge, on a small spot, an electron emitted from the photoelectric surface 31.

For example, when an electron emission tube 1 does not include an electron-permeable membrane 44, it is necessary to keep an internal space S including a first region S1, in which a photoelectric surface 31 is provided, in a vacuum state by a gate valve 5 and a housing 2. In this case, there is a possibility that it is not possible to keep the internal space S in a degree of vacuum, with which sensitivity of the photoelectric surface 31 can be stably maintained for a long time, due to a small leak from a gasket or the gate valve 5. Note that in the electron emission tube 1 described in the present embodiment, there is a possibility that a degree of vacuum of a second region S2 is not completely the same with a degree of vacuum of a first region S1 due to a small leak from a gasket or the gate valve 5. However, even when a small difference is generated between the degree of vacuum of the first region S1 and that of the second region S2, there is a low possibility that an atmospheric pressure difference in a degree in which an electron-permeable membrane 44 is broken is generated.

Also, the electron irradiation device 10 includes the electron emission tube 1 and the housing chamber 11. The electron emission tube 1 is attached to the housing chamber 11. The housing chamber 11 houses the irradiated body 15. According to the electron irradiation device 10, it becomes possible to irradiate the irradiated body 15 in the housing chamber 11 with an electron emitted from the electron emission tube 1. After a space in the housing chamber 11 is evacuated, each of the first region S1, the second region S2, and the internal space of the housing chamber 11 is in a vacuum state. Thus, since an atmospheric pressure difference between the first region S1 and a space constituted by connecting the second region S2 and the internal space of the housing chamber 11 is small even when the other end side in the X-axis direction of the electron emission tube 1 is brought into an open state by the gate valve 5, force applied to the electron-permeable membrane 44 due to the atmospheric pressure difference is reduced. As a result, it becomes possible to reduce a thickness of the electron-permeable membrane 44.

The electron irradiation device 10 includes the detector 16 arranged in the housing chamber 11. The detector 16 detects a response signal generated by irradiating the irradiated body 15 with an electron. Thus, it becomes possible to perform observation or inspection of the irradiated body 15.

When the electron irradiation device 10 is used after the electron emission tube 1 is attached to the housing chamber 11, the second region S2 is connected to the evacuated internal space of the housing chamber 11. Thus, a degree of vacuum of the second region S2 may be slightly lower than that of the first region S1. However, even when the degree of vacuum of the second region S2 is deteriorated and a small difference from the degree of vacuum of the first region S1 is generated, there is low possibility that an atmospheric pressure difference in a degree in which the electron-permeable membrane 44 is broken is generated. Also, the photoelectric surface 31 may be deteriorated when being exposed to water or oxygen. When the second region S2 is connected to the internal space of the housing chamber 11, water or oxygen may enter the electron emission tube 1. However, since the electron-permeable membrane 44 is provided between the first region S1 including the photoelectric surface 31 and the second region S2, a possibility that the photoelectric surface 31 is exposed to water or oxygen is reduced.

Since the electron emission tube 1 including the photoelectric surface 31 is attached to the housing chamber 11, it becomes possible to manufacture the electron emission tube 1 separately from manufacture of the whole electron irradiation device 10. Thus, it becomes possible to manufacture the high sensitive photoelectric surface 31 in a highly reproducible manner.

The electron emission tube 1 included in the electron irradiation device 10 includes a deflection coil 72a and a deflection coil 72b. A position where an electron passes through the electron-permeable membrane 44 is adjusted by the deflection coil 72a and the deflection coil 72b. Since the two deflection coils 72a and 72b are included, it becomes possible to make an adjustment in such a manner that an electron emitted from any position in the photoelectric surface 31 passes through the same position in the electron-permeable membrane 44 vertically to the electron-permeable membrane 44.

In a case where the photoelectric surface 31 is an alkali photoelectric surface, sensitivity of a part where light enters the alkali photoelectric surface may be gradually deteriorated. Thus, there is a case where it is possible to acquire original sensitivity by moving a position where light enters the alkali photoelectric surface. However, there is a case where a trajectory of an electron is deviated and the electron does not appropriately pass through a region, in which a center axis extending in the X-axis direction of the electron emission tube 1 is set to a center, in the electron-permeable membrane 44 along the center axis when a position where light enters the alkali photoelectric surface is moved. In such a case, a moving direction of an electron emitted from the alkali photoelectric surface can be adjusted to be toward the center axis by the deflection coil 72a and the moving direction of the electron can be adjusted to face a direction along the center axis by the deflection coil 72b. Thus, even when a part of the alkali photoelectric surface is deteriorated and a position where light enters is changed, it becomes possible to make an electron emitted from the alkali photoelectric surface pass, along the center axis, through the region with the center axis being the center in the electron-permeable membrane 44. As a result, it becomes possible to appropriately irradiate the irradiated body 15 with an electron without adjusting a lens or the like in the housing chamber 11.

In a method of manufacturing an electron emission tube 1, a branch tube 83 connected to a first region S1 and a branch tube 84 connected to a second region S2 are connected to a vacuum pump 81 through a common tube 82. Thus, the first region S1 and the second region S2 are simultaneously evacuated by an exhaust device 8. Thus, since an atmospheric pressure difference between the first region S1 and the second region S2 becomes small, force that is due to the atmospheric pressure difference and that is applied to an electron-permeable membrane 44 arranged between the first region S1 and the second region S2 is reduced in a manufacturing stage of the electron emission tube 1. As a result, it becomes possible to reduce a thickness of the electron-permeable membrane 44.

Note that an electron emission tube, an electron irradiation device, and a method of manufacturing an electron emission tube according to the present disclosure are not limited to the above embodiment.

In the above embodiment, the electron emission tube 1 includes the electron source 3 having the photoelectric surface 31. However, this is not the limitation. The electron source 3 may be a thermionic source that emits an electron to the internal space S by heating of a cathode. As materials of the cathode used in the thermionic source, there are tungsten, lanthanum hexaboride (LaB₅), oxide, and the like. In this case, it becomes possible to emit an electron to the internal space S by applying heat to the electron source 3.

A method of manufacturing an electron emission tube 1 including such a thermionic source includes the air exhausting step and the sealing step described in the above embodiment. More specifically, after degassing and baking of a first region S1 including the thermionic source is performed, the first region S1 is sealed in such a manner that a vacuum state is maintained. After manufacture of the electron emission tube 1, the vacuum state of the first region S1 is kept by a housing 2, an electron-permeable membrane 44, and the like. As a result, it becomes possible to improve stability and a product life of the thermionic source.

An electron source 3 may be a field emission electron source that emits an electron from a cathode to an internal space S by application of voltage between the cathode and an anode. As the field emission electron source, there are a thermal field emitter (TFE) that uses heat and an electric field, a cold field emitter (CFE) that uses an electric field only, and a field emitter array (FEA). Note that there is a case where the TFE is called a thermal field emission electron source.

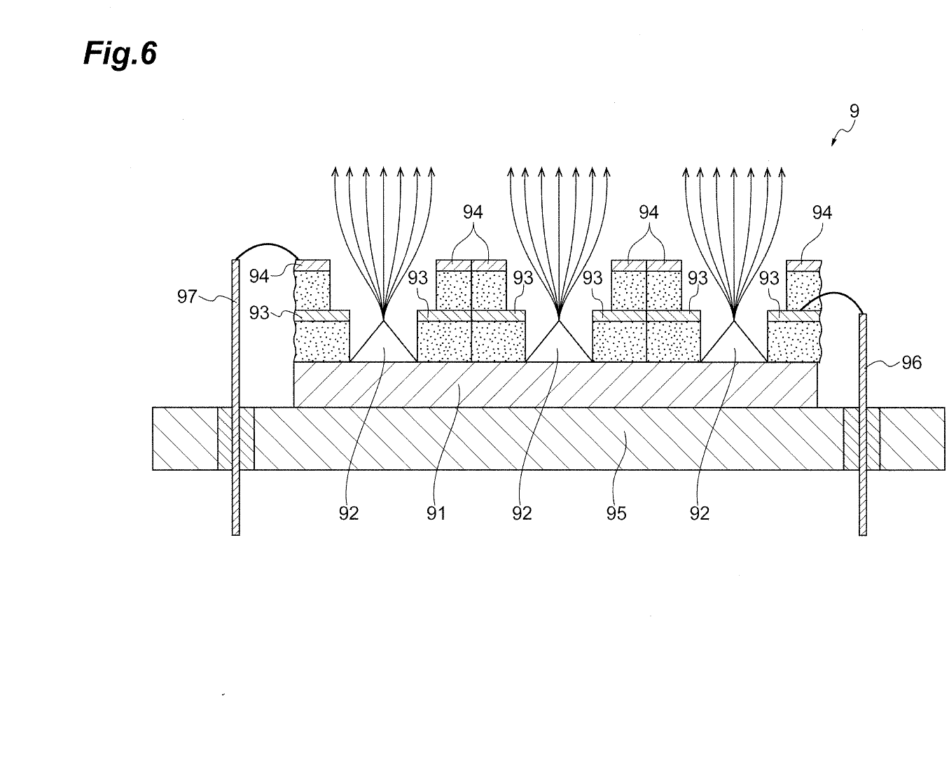

FIG. 6 is a view illustrating another example of an electron source. In FIG. 6, an FEA 9 (field emission electron source) as an electron source is illustrated. The FEA 9 is manufactured, for example, by microfabrication of a silicon substrate. The FEA 9 includes a substrate 91, an emitter 92, a gate electrode 93, a gate electrode 94, a metal stem 95, a pin 96, and a pin 97. A plurality of emitters 92, a plurality of gate electrodes 93, and a plurality of gate electrodes 94 are provided in the substrate 91. The substrate 91 is provided on the metal stem 95. Voltage of a negative potential is applied to the plurality of emitters 92 through the metal stem 95. Voltage of a positive potential is applied to each of the plurality of gate electrodes 93 through the pin 96. Note that in FIG. 6, only a pin 96 that applies voltage to one gate electrode 93 is illustrated. Voltage of a positive potential is applied to each of the plurality of gate electrodes 94 through the pin 97. Note that in FIG. 6, only a pin 97 that applies voltage to one gate electrode 94 is illustrated. When voltage of a positive potential is applied to a pair of gate electrodes 93 sandwiching one of the plurality of emitters 92, an electric field is generated between the emitter 92 and the pair of gate electrodes 93 and an electron is emitted from a leading end of the emitter 92. The gate electrodes 94 converge the electron emitted from the emitter 92.

A method of manufacturing an electron emission tube 1 including such an FEA 9 (field emission electron source) includes the air exhausting step and the sealing step described in the above embodiment. More specifically, after degassing and baking of a first region S1 including the FEA 9 is performed, the first region S1 is sealed in such a manner that a vacuum state is maintained. After manufacture of the electron emission tube 1, the vacuum state of the first region S1 is kept by a housing 2, an electron-permeable membrane 44, and the like. As a result, it becomes possible to improve stability and a product life of the FEA 9.

The electron-permeable membrane 44 is a membrane made of single-layer graphene in the above embodiment, but the electron-permeable membrane 44 is not limited to this configuration. The electron-permeable membrane 44 may be a membrane made of multi-layer graphene with two or more layers. The electron-permeable membrane 44 may be a membrane made of a single-layer (mono layer) substance other than graphene. The single-layer substance is a sheet-shaped single atom layer substance constituted by a single atomic layer and a thickness of one atom, or a sheet-shaped substance a thickness of which is around that of one atom. A single-layer substance may be constituted by tungsten disulfide (WS₂) or molybdenum disulfide (MoS₂). When the electron-permeable membrane 44 is constituted by a single-layer substance, the electron-permeable membrane 44 becomes thin in thickness, and it becomes possible to reduce an influence on an electron passing through the electron-permeable membrane 44.

An electron-permeable membrane 44 may be a silicon nitride membrane. Since internal stress generated in manufacturing process of the silicon nitride membrane is small, it is possible to reduce a thickness of the silicon nitride membrane. For example, in a case where a diameter of the silicon nitride membrane is 0.25 mm, it is possible to make the thickness of the silicon nitride membrane around 30 nm. Thus, it becomes possible to reduce an influence on an electron passing through the electron-permeable membrane 44.

In the above embodiment, the partition part 4 including the electron-permeable membrane 44 is provided between the flange 24 and the flange 26. However, the position of the electron-permeable membrane 44 is not limited to the above-described position. It is only necessary that a partition part 4 including an electron-permeable membrane 44 is placed between an electron source 3 and a gate valve 5 in such a manner as to divide an internal space S into a first region S1 including the electron source 3 and a second region S2 including the gate valve 5. For example, a partition part 4 may be provided in such a manner as to be fixed to an acceleration electrode 6.

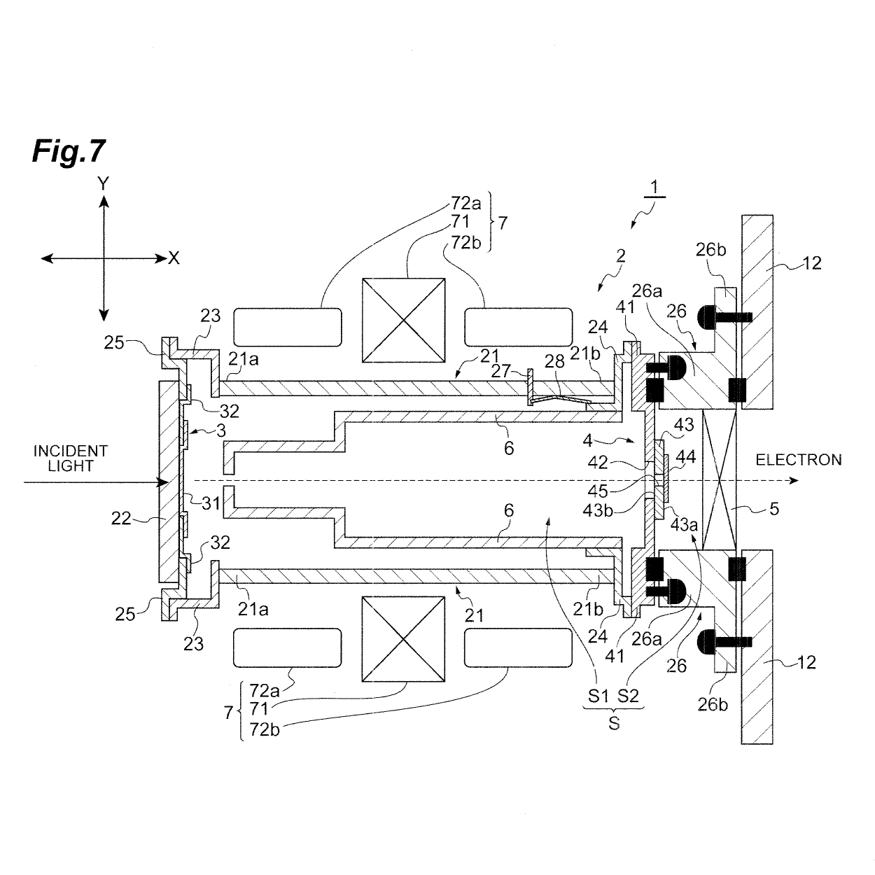

As illustrated in FIG. 7, the electron emission tube 1 may further include a through pin 27 and a getter 28. The through pin 27 is provided in the side wall part 21. The through pin 27 penetrates the side wall part 21 in a direction orthogonal to the X-axis direction, while maintaining an airtight seal. One end of the through pin 27 is located on the outside of the housing 2, and the other end of the through pin 27 is connected to one end of the getter 28 on the inside of the housing 2. The getter 28 is positioned in the first region S1. The other end of the getter 28 is connected to the flange 24. The getter 28 is, for example, a non-vapor-deposition-type getter. A voltage is applied to the getter 28 via the through pin 27, so as to heat and activate the getter 28. As a result, the getter 28 causes water and gas (e.g. oxygen) remaining in the first region S1 to adhere, and maintains the first region S1 under a high vacuum. This configuration reduces the possibility of the photoelectric surface 31 being exposed to water and oxygen, which would cause the photoelectric surface 31 to deteriorate.

What is claimed is:

1. An electron emission tube comprising:
a housing in which an internal space is provided and which is configured to keep the internal space in vacuum;
an electron source arranged on a first end side in one direction of the housing and configured to generate an electron;
a gate valve arranged on a second end side in the one direction of the housing and capable of switching the second end side between an open state and a blocked state; and
a partition part placed between the electron source and the gate valve and configured to divide the internal space into a first region including the electron source and a second region including the gate valve,
wherein the partition part includes an electron-permeable membrane configured to transmit the electron.

2. The electron emission tube according to claim 1, wherein a potential of the electron-permeable membrane is a ground potential.

3. The electron emission tube according to claim 1, further comprising an acceleration electrode which is arranged in the internal space and to which voltage with a potential higher than a potential of the electron source is applied.

4. The electron emission tube according to claim 1, wherein the electron-permeable membrane is a membrane made of a single-layer substance.

5. The electron emission tube according to claim 1, wherein the electron-permeable membrane is a membrane made of single-layer or multi-layer graphene.

6. The electron emission tube according to claim 1, wherein the electron-permeable membrane is a silicon nitride membrane.

7. The electron emission tube according to claim 4, wherein the single-layer substance is constituted by tungsten disulfide or molybdenum disulfide.

8. The electron emission tube according to claim 1, wherein the partition part includes a substrate having a first surface intersecting with the one direction and a second surface intersecting with the one direction and being provided on an opposite side of the first surface,
a hole penetrating through the substrate in the one direction is provided in the substrate, and
the electron-permeable membrane is provided on the first surface and covers the hole.

9. The electron emission tube according to claim 8, wherein the partition part includes a holding member having an opening,
the substrate is fixed to the holding member by brazing or a metal seal, and
the opening and the hole are arranged in such a manner as to overlap with each other.

10. The electron emission tube according to claim 1, wherein the electron source includes a photoelectric surface configured to generate the electron when being irradiated with light.

11. The electron emission tube according to claim 10, wherein the photoelectric surface is an alkali photoelectric surface.

12. The electron emission tube according to claim 1, wherein the electron source is a thermionic source or a field emission electron source.

13. An electron irradiation device configured to irradiate an irradiated body with an electron, comprising:
the electron emission tube according to claim 1; and
a housing chamber to which the electron emission tube is attached and which is configured to house the irradiated body.

14. The electron irradiation device according to claim 13, further comprising a detector arranged in the housing chamber and configured to detect a response signal generated by irradiating the irradiated body with an electron.

15. A method of manufacturing the electron emission tube according to claim 1, comprising:
evacuating the first region and the second region by an exhaust device,
wherein the exhaust device includes a vacuum pump, a common tube extending from the vacuum pump, a first branch tube extending from the common tube and connected to the first region, and a second branch tube extending from the common tube and connected to the second region.
